(19) United States
(12) Patent Application Publication
(10) Pub. No.: US 2025/0380378 A1
(43) Pub. Date: Dec. 11, 2025

(54) LIQUID COOLING DEVICE

(71) Applicants: IINVENTEC (PUDONG) TECHNOLOGY CORPORATION, Shanghai City (CN); INVENTEC CORPORATION, Taipei City (TW)

(72) Inventors: Kai-Yang TUNG, Taipei City (TW); Hung-Ju CHEN, Taipei City (TW); Yin Po CHIU, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 18/944,825

(22) Filed: Nov. 12, 2024

(30) Foreign Application Priority Data
Jun. 5, 2024 (CN) 202410727487.7

(51) Int. Cl. H05K 7/20

(52) U.S. Cl. CPC H05K 7/20254; H05K 7/20272; H05K 7/20309; H05K 7/20318; H05K 7/20327

(57) ABSTRACT

A liquid cooling device includes a first cold plate, a second cold plate and a side cover. The second cold plate is stacked on the first cold plate. The side cover is disposed on one side of the first cold plate and the second cold plate. In addition, the side cover and the one side of the first cold plate and the second cold plate together form a connection channel. The connection channel is in fluid communication with the first cold plate and the second cold plate, and the connection channel extends from one end of the first cold plate, the second cold plate and the side cover to another end of the first cold plate, the second cold plate and the side cover.

### CROSS-REFERENCE TO RELATED APPLICATIONS

This non-provisional application claims priority under 35 U.S.C. § 119 (a) on Patent Application No(s). 202410727487.7 filed in China, on Jun. 5, 2024, the entire contents of which are hereby incorporated by reference.

### BACKGROUND OF THE INVENTION

### Technical Field of the Invention

The invention relates to a liquid cooling device, especially to a liquid cooling device having two cold plates and a connection channel.

### Description of the Related Art

The operation of electronic devices usually generates a significant amount of heat. If the heat is not effectively dissipated, it can cause the internal electronic components to overheat, leading to malfunctions or system crashes. Therefore, electronic devices are usually equipped with corresponding cooling systems to ensure that electronic components do not exceed their specified operating temperature range. High-performance electronic devices, in particular, are often provided with liquid cooling systems, such as water cooling plates, to provide better heat dissipation.

One conventional liquid cooling system design features a condenser disposed between two cold plates to dissipate heat more evenly. The two cold plates are typically connected by pipes. However, the standard size of the pipes is smaller than those of the cold plates, increasing flow resistance and reducing cooling efficiency. While reducing the size of the condenser and increasing the size of the pipes can decrease flow resistance, it also reduces the heat exchange area due to the smaller condenser, leading to decreased cooling efficiency. Therefore, how to maintain cooling efficiency while decreasing flow resistance and without reducing the heat exchange area is a key challenge for researchers in this field.

### SUMMARY OF THE INVENTION

The invention provides a liquid cooling device capable of maintaining cooling efficiency while decreasing flow resistance and without reducing heat exchange area.

One embodiment of the invention provides a liquid cooling device including a first cold plate, a second cold plate and a side cover. The second cold plate is stacked on the first cold plate. The side cover is disposed on one side of the first cold plate and the second cold plate. In addition, the side cover and the one side of the first cold plate and the second cold plate together form a connection channel. The connection channel is in fluid communication with the first cold plate and the second cold plate, and the connection channel extends from one end of the first cold plate, the second cold plate and the side cover to another end of the first cold plate, the second cold plate and the side cover.

According to the liquid cooling device as discussed in the above embodiment, since the connection channel extends from one end to another end of the first cold plate, the second cold plate and the side cover, the connection channel can have larger width, which eliminates the need to reduce the size of the condenser, the first inner fin, the second inner fins, the third inner fin or the fourth inner fins, thus maintaining the heat exchange area. Therefore, the heat dissipation efficiency of the liquid cooling device can be enhanced.

### BRIEF DESCRIPTION OF THE DRAWINGS

The invention will become more fully understood from the detailed description given hereinbelow and the accompanying drawings which are given by way of illustration only and thus are not limitative of the invention and wherein:

FIG. 1 is a perspective view of a liquid cooling device according to one embodiment of the invention;

FIG. 2 is another perspective view of the liquid cooling device in FIG. 1;

FIG. 3 is a cross-sectional view of a first cold plate of the liquid cooling device in FIG. 1;

FIG. 4 is a cross-sectional view of the liquid cooling device taken along line 4-4 in FIG. 3;

FIG. 5 is a cross-sectional view of the liquid cooling device taken along line 5-5 in FIG. 3; and

FIG. 6 is a cross-sectional view of a second cold plate of the liquid cooling device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

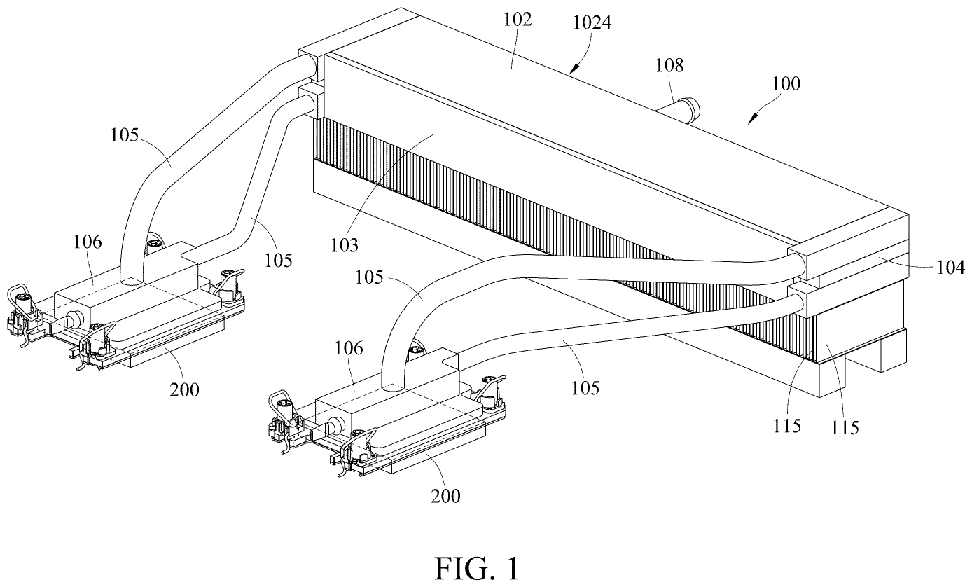

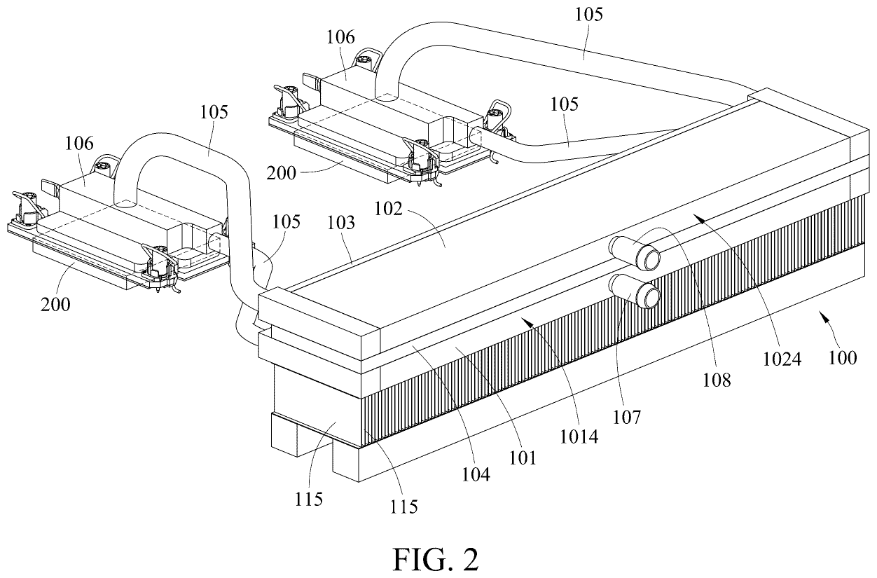

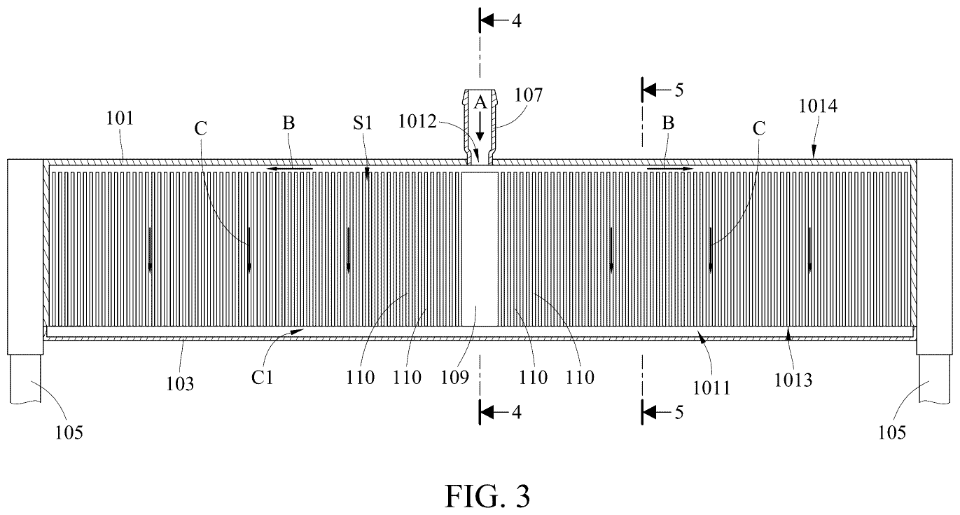

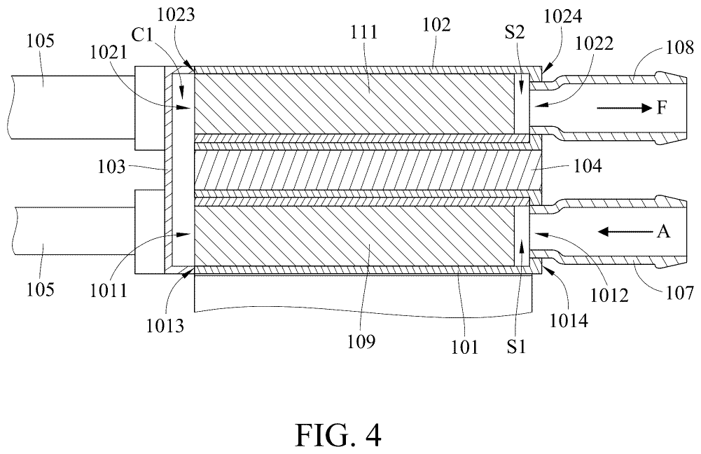

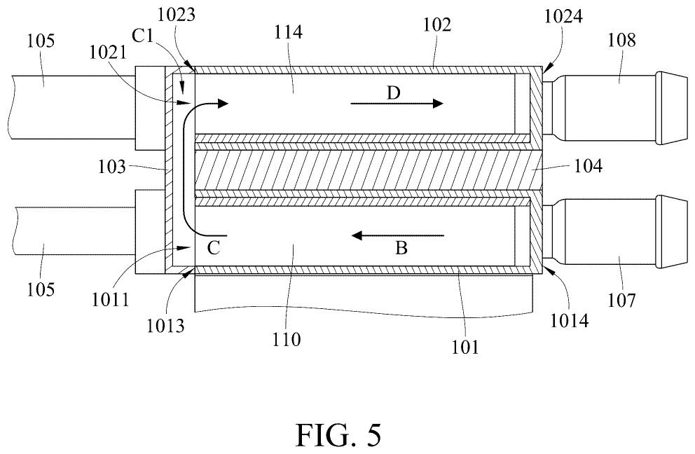

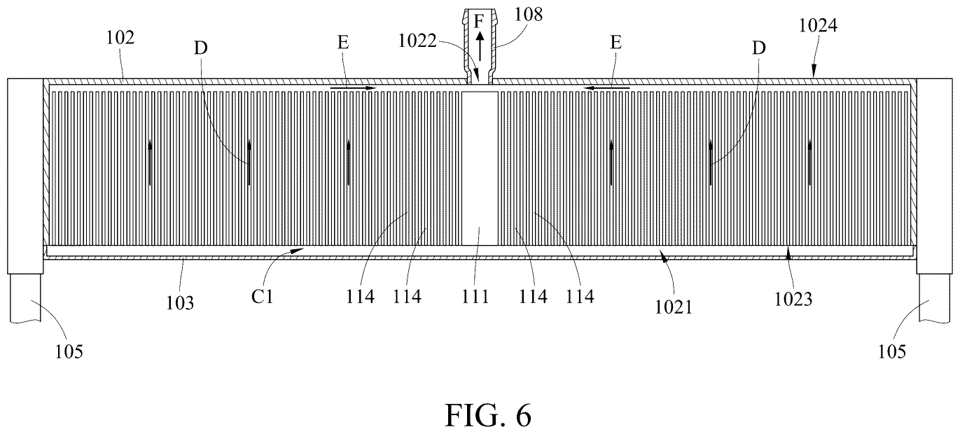

Referring to FIG. 1 to FIG. 6, FIG. 1 is a perspective view of a liquid cooling device according to one embodiment of the invention, FIG. 2 is another perspective view of the liquid cooling device in FIG. 1, FIG. 3 is a cross-sectional view of a first cold plate of the liquid cooling device in FIG. 1, FIG. 4 is a cross-sectional view of the liquid cooling device taken along line 4-4 in FIG. 3, FIG. 5 is a cross-sectional view of the liquid cooling device taken along line 5-5 in FIG. 3, and FIG. 6 is a cross-sectional view of a second cold plate of the liquid cooling device in FIG. 1.

In this embodiment, a liquid cooling device 100 is provided. The liquid cooling device 100 is configured to be disposed on a server (not shown in figure), and includes a first cold plate 101, a second cold plate 102, a side cover 103, a condenser 104, a plurality of thermosiphon pipes 105, two evaporators 106, a liquid inlet pipe 107 and a liquid outlet pipe 108. The first cold plate 101 and the second cold plate 102 are configured to accommodate a first coolant (not shown in figure). The second cold plate 102 is stacked on the first cold plate 101. The first cold plate 101 has a first side 1013 and a second side 1014 that are opposite to each other. The second cold plate 102 has a third side 1023 and a fourth side 1024 that are opposite to each other. The side cover 103 is disposed on the first side 1013 of the first cold plate 101 and the third side 1023 of the second cold plate 102.

The first side 1013 of the first cold plate 101, the third side 1023 of the second cold plate 102 and the side cover 103 together form a connection channel C1. The first side 1013 of the first cold plate 101 has a first connection port 1011. In other words, the first connection port 1011 is located on a side of the first cold plate 101 that is closest to the connection channel C1. The third side 1023 of the second cold plate 102 has a second connection port 1021. In other words, the second connection port 1021 is located on a side of the second cold plate 102 that is closest to the connection channel C1. The connection channel C1 is in fluid communication with the first cold plate 101 and the second cold plate 102 through the first connection port 1011 and the second connection port 1021.

The second side 1014 of the first cold plate 101 has a liquid inlet 1012. In other words, the liquid inlet 1012 and the connection channel C1 are respectively located on two opposite sides of the first cold plate 101. The liquid inlet pipe 107 is disposed on the liquid inlet 1012 and configured for the first coolant to enter. The fourth side 1024 of the second cold plate 102 has a liquid outlet 1022. In other words, the liquid outlet 1022 and the connection channel C1 are respectively located on two opposite sides of the second cold plate 102. The liquid outlet pipe 108 is disposed on the liquid outlet 1022 and configured for the first coolant to enter. In addition, the first coolant is, for example, water, but the invention is not limited thereto.

In this embodiment, the connection channel C1 extends from one end of the first cold plate 101, the second cold plate 102 and the side cover 103 to another end of the first cold plate 101, the second cold plate 102 and the side cover 103. The first connection port 1011 extends from one end of the first cold plate 101 to another end of the first cold plate 101. The second connection port 1021 extends from one end of the second cold plate 102 to another end of the second cold plate 102. In other words, compared to the narrower connection channel of a conventional liquid cooling device, the connection channel C1 in this embodiment has a larger width, which reduces flow resistance to the first coolant, thereby enhancing heat dissipation efficiency.

The condenser 104, the thermosiphon pipes 105 and the two evaporators 106 are configured to accommodate a second coolant (not shown in figure). The condenser 104 is disposed between the first cold plate 101 and the second cold plate 102. In detail, the first cold plate 101 is located at a bottom of the condenser 104, and the second cold plate 102 is located at a top of the condenser 104. The thermosiphon pipes 105 are respectively connected to two opposite ends of the condenser 104. The two evaporators 106 are respectively connected to ends of the thermosiphon pipes 105 that are farthest away from the condenser 104. The two evaporators 106 are configured to be thermally coupled to two heat sources 200. The term “thermally coupled to” refers to thermal contact or connection through a thermal conductive medium. Additionally, the term “thermosiphon” refers to a system that utilizes the density difference between the liquid and vapor phases of a cooling fluid. When heated, a portion of the cooling fluid vaporizes, creating a two-phase mixture that drives the heat transfer cycle. Additionally, the second coolant is, for example, a refrigerant, and the heat sources 200 are, for example, CPUs, but the invention is not limited thereto.

When the second coolant absorbs heat generated by the two heat sources 200 at the two evaporators 106 and then flows to the condenser 104 through the thermosiphon pipes 105, the first coolant absorbs and removes the heat that is transferred to the second coolant by flowing in the first cold plate 101, the connection channel C1 and the second cold plate 102. Therefore, the two heat sources 200 can be cooled.

In this embodiment, the liquid cooling device 100 may further include a first inner fin 109, a plurality of second inner fins 110, a third inner fin 111 and a plurality of fourth inner fins 114. The first cold plate 101 has a first accommodation space S1. The first accommodation space S1, the first connection port 1011 and the liquid inlet 1012 are in fluid communication with each other. The first inner fin 109, the second inner fins 110, the third inner fin 111 and the fourth inner fins 114 are, for example, plate-shaped. The first inner fin 109 and the second inner fins 110 are disposed in the first accommodation space S1, and the second inner fins 110 are respectively located on two opposite sides of the first inner fin 109. One end of the first inner fin 109 corresponds to the liquid inlet 1012. In addition, a thickness of the first inner fin 109 is, for example, greater than a thickness of each of the second inner fins 110, but the invention is not limited thereto. The first coolant entering through the liquid inlet 1012 can be evenly distributed by the inclusion of the first inner fin 109 with greater thickness and having one end of the first inner fin 109 corresponding to the liquid inlet 1012 in the liquid cooling device 100. Furthermore, an extension direction of the first inner fin 109 and an extension direction of the second inner fins 110 are, for example, perpendicular to an extension direction of the side cover 103, but the invention is not limited thereto.

The second cold plate 102 has a second accommodation space S2. The second accommodation space S2, the second connection port 1021 and the liquid outlet 1022 are in fluid communication with each other. In other words, the first accommodation space S1 is in fluid communication with the second accommodation space S2 through the first connection port 1011, the connection channel C1 and the second connection port 1021. The third inner fin 111 and the fourth inner fins 114 are disposed in the second accommodation space S2, and the fourth inner fins 114 are respectively located on two opposite sides of the third inner fin 111. One end of the third inner fin 111 corresponds to the liquid outlet 1022. In addition, a thickness of the third inner fin 111 is greater than a thickness of each of the fourth inner fins 114, but the invention is not limited thereto. The distributed first coolant can be converged at the liquid outlet 1022 by the inclusion of the third inner fin 111 with greater thickness and having one end of the third inner fin 111 corresponding to the liquid inlet 1012 in the liquid cooling device 100. Furthermore, an extension direction of the third inner fin 111 and an extension direction of the fourth inner fins 114 are, for example, perpendicular to an extension direction of the side cover 103, but the invention is not limited thereto.

In this embodiment, since the extension direction of the first inner fin 109 and the extension direction of the second inner fins 110 are perpendicular to the extension direction of the side cover 103, and the extension direction of the third inner fin 111 and the extension direction of the fourth inner fins 114 are perpendicular to the extension direction of the side cover 103, a flow direction of the distributed first coolant in the first accommodation space S1 and the second accommodation space S2 is parallel to the extension directions of the first inner fin 109, the second inner fins 110, the third inner fin 111 and the fourth inner fins 114.

In this embodiment, the liquid cooling device 100 may further include a plurality of outer fins 115. The outer fins 115 are disposed on one side of the first cold plate 101 that is farthest away from the second cold plate 102. Therefore, the cooling efficiency can be further enhanced by having airflow generated by a fan (not shown in figure) of the server flowing through the outer fins 115. Moreover, the temperature of the airflow generated by the fan of the server may be decreased by 5.6° C. after flowing through the outer fins 115 by the inclusion of the first inner fin 109, the second inner fins 110, the third inner fin 111, the fourth inner fins 114 and the outer fins 115 in the liquid cooling device 100.

In this embodiment, since the connection channel C1 extends from one end to another end of the first cold plate 101, the second cold plate 102 and the side cover 103, the connection channel C1 can have larger width, which eliminates the need to reduce the size of the condenser 104, the first inner fin 109, the second inner fins 110, the third inner fin 111 or the fourth inner fins 114, thus maintaining the heat exchange area. Therefore, the heat dissipation efficiency of the liquid cooling device 100 can be enhanced.

Moreover, since the flow direction of the distributed first coolant in the first accommodation space S1 and the second accommodation space S2 is parallel to the extension directions of the first inner fin 109, the second inner fins 110, the third inner fin 111 and the fourth inner fins 114, in addition to increasing the width of the connection channel C1 without reducing the size of the first inner fin 109, the second inner fins 110, the third inner fin 111 and the fourth inner fins 114, the number of times the distributed first coolant changes its flow direction within the first accommodation space S1 and the second accommodation space S2 can also be reduced to shorten the flow path, thereby reducing the flow resistance to the first coolant and further improving the heat dissipation efficiency of the liquid cooling device 100.

Additionally, by the inclusion of the connection channel C1, the first inner fin 109, the second inner fins 110, the third inner fin 111 and the fourth inner fins 114 in the liquid cooling device 100, the pressure drop of the first coolant can be reduced. Therefore, the flow resistance to the first coolant can be further reduced to further increase the heat dissipation efficiency of the liquid cooling device 100. For example, compared to a conventional liquid cooling device (which having a connection channel smaller than the connection channel C1 in this embodiment), the liquid cooling device 100 in this embodiment can reduce the pressure drop of the first coolant from, for example, 475.9 Pa to 225.6 Pa. In other words, the liquid cooling device 100 in this embodiment can reduce the pressure drop of the first coolant, for example, by 250.3 Pa (i.e., a reduction of approximately 53%).

In this embodiment, the first cold plate 101, located at the bottom of the condenser 104, is configured for the first coolant to enter, and the second cold plate 102, located at the top of the condenser 104, is configured for the first coolant to exit, but the invention is not limited thereto. In other embodiment, the flow direction of the first coolant can be reversed. In other words, it may be the second cold plate that is located at the top of the condenser and configured for the first coolant to enter, and it may be the first cold plate that is located at the bottom of the condenser and configured for the first coolant to exit.

In this embodiment, the configuration within the first cold plate 101 is symmetrical, and the configuration within the second cold plate 102 is also symmetrical, but the invention is not limited thereto. In other embodiment, when the configuration of the thermosiphon pipes needs to be adjusted due to different configurations within the server, the configurations within the first cold plate and the second cold plate can also be adjusted accordingly to match the structure of the thermosiphon pipes.

In this embodiment, the connection channel C1 extends from one end to another end of the first cold plate 101, the second cold plate 102 and the side cover 103, the first connection port 1011 extends from one end to another end of the first cold plate 101, and the second connection port 1021 extends from one end to another end of the second cold plate 102, but the invention is not limited thereto. In other embodiment, the liquid cooling device may also include a partition to divide the connection channel, the first connection port and the second connection port into two separate sections.

In this embodiment, the first inner fin 109, the second inner fins 110, the third inner fin 111 and the fourth inner fins 114 are plate-shaped, but the invention is not limited thereto. In other embodiment, the first inner fin, second inner fins, third inner fin and fourth inner fins may be in various shapes.

Please refer to FIG. 3 to FIG. 6 again. In this embodiment, when the first coolant flows into the first accommodation space S1 from the liquid inlet pipe 107 along a direction A, the first coolant is first obstructed by the first inner fin 109 and temporarily diverges at the liquid inlet 1012, and then flows along a direction B and a direction C respectively into the connection channel C1 within the first accommodation space S1. Subsequently, the distributed first coolant temporarily converges in the connection channel C1 and then flows along the direction C into the second accommodation space S2 within the connection channel C1.

Then, the converged first coolant is obstructed by the second inner fins 110 within the second accommodation space S2 and temporarily diverges again, and then flows along a direction D and a direction E respectively into the liquid outlet pipe 108 within the second accommodation space S2. Subsequently, the distributed first coolant converges at the liquid outlet 1022, and then flows along a direction F out of the liquid outlet pipe 108 from the second accommodation space S2, initiating the next circulation. Therefore, the cooling cycle of the first coolant is completed.

According to the rack liquid cooling device as described in the above embodiment, since the connection channel extends from one end to another end of the first cold plate, the second cold plate and the side cover, the connection channel can have larger width, which eliminates the need to reduce the size of the condenser, the first inner fin, the second inner fins, the third inner fin or the fourth inner fins, thus maintaining the heat exchange area. Therefore, the heat dissipation efficiency of the liquid cooling device can be enhanced.

Additionally, since the flow direction of the distributed first coolant in the first accommodation space and the second accommodation space is parallel to the extension directions of the first inner fin, the second inner fins, the third inner fin and the fourth inner fins, in addition to increasing the width of the connection channel without reducing the size of the first inner fin, the second inner fins, the third inner fin and the fourth inner fins, the number of times the distributed first coolant changes its flow direction within the first accommodation space and the second accommodation space can also be reduced to shorten the flow path, thereby reducing the flow resistance to the first coolant and further improving the heat dissipation efficiency of the liquid cooling device.

Moreover, by the inclusion of the connection channel, the first inner fin, the second inner fins, the third inner fin and the fourth inner fins in the liquid cooling device, the pressure drop of the first coolant can be reduced. Therefore, the flow resistance to the first coolant can be further reduced to further increase the heat dissipation efficiency of the liquid cooling device.

In one embodiment of the invention, the liquid cooling device is applicable to the server, which can be used for artificial intelligence (AI) computing, edge computing, and can also be used as a 5G server, a cloud server or a server for vehicle-to-everything.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A liquid cooling device comprising:
a first cold plate;
a second cold plate stacked on the first cold plate; and
a side cover disposed on one side of the first cold plate and the second cold plate;
wherein the side cover and the one side of the first cold plate and the second cold plate together form a connection channel, the connection channel is in fluid communication with the first cold plate and the second cold plate, and the connection channel extends from one end of the first cold plate, the second cold plate and the side cover to another end of the first cold plate, the second cold plate and the side cover.

2. The liquid cooling device according to claim 1, wherein the first cold plate has a first connection port on a side that is closest to the connection channel, the second cold plate has a second connection port on a side that is closest to the connection channel, the connection channel is in fluid communication with the first cold plate and the second cold plate through the first connection port and the second connection port, the first connection port extends from one end of the first cold plate to another end of the first cold plate, and the second connection port extends from one end of the second cold plate to another end of the second cold plate.

3. The liquid cooling device according to claim 2, further comprising a first inner fin and a plurality of second inner fins, wherein the first cold plate has a first accommodation space connected to the first connection port, the first inner fin and the plurality of second inner fins are disposed in the first accommodation space, and the plurality of second inner fins are respectively located on two opposite sides of the first inner fin.

4. The liquid cooling device according to claim 3, wherein a thickness of the first inner fin is greater than a thickness of each of the plurality of second inner fins.

5. The liquid cooling device according to claim 3, wherein an extension direction of the first inner fin and an extension direction of the plurality of second inner fins are perpendicular to an extension direction of the side cover.

6. The liquid cooling device according to claim 3, further comprising a third inner fin and a plurality of fourth inner fins, wherein the second cold plate has a second accommodation space connected to the second connection port, the third inner fin and the plurality of fourth inner fins are disposed in the second accommodation space, and the plurality of fourth inner fins are respectively located on two opposite sides of the third inner fin.

7. The liquid cooling device according to claim 6, wherein a thickness of the third inner fin is greater than a thickness of each of the plurality of fourth inner fins.

8. The liquid cooling device according to claim 6, wherein an extension direction of the third inner fin and an extension direction of the plurality of fourth inner fins are perpendicular to an extension direction of the side cover.

9. The liquid cooling device according to claim 1, further comprising a condenser, a plurality of thermosiphon pipes and two evaporators, wherein the condenser is disposed between the first cold plate and the second cold plate, the plurality of thermosiphon pipes are respectively connected to two opposite ends of the condenser, the two evaporators are respectively connected to ends of the plurality of thermosiphon pipes that are farthest away from the condenser, and the two evaporators are configured to be in thermal contact with two heat sources.

10. The liquid cooling device according to claim 1, further comprising a plurality of outer fins disposed on a side of the first cold plate that is farthest away from the second cold plate.
